(19) United States
(12) Patent Application Publication
(10) Pub. No.: US 2025/0343207 A1
(43) Pub. Date: Nov. 6, 2025

(54) LAMINATED MICRO-LED LIGHT DISPLAY WITH MICRO-REFLECTORS AND METHOD OF FABRICATING

(71) Applicant: GM GLOBAL TECHNOLOGY OPERATIONS LLC, Detroit, MI (US)

(72) Inventors: Jonglee Park, Novi, MI (US); Julien P. Mourou, Bloomfield Hills, MI (US)

(73) Assignee: GM GLOBAL TECHNOLOGY OPERATIONS LLC, Detroit, MI (US)

(21) Appl. No.: 18/651,997

(22) Filed: May 1, 2024

(51) Int. Cl. H01L 25/075; B32B 3/30; B32B 17/10; H01L 33/60

(52) U.S. Cl. CPC H01L 25/0753; B32B 3/30; B32B 17/10036; B32B 17/10495; H10H 20/856; B32B 2307/412; B32B 2307/416; B32B 2457/20; B32B 2605/00; H10H 20/0363

(57) ABSTRACT

A method of fabricating micro-reflective surfaces disposed on a surface of, or disposed inside of, a window or mirror. A micro-Light Emitting Diode (micro-LED) display for vehicle windows or windshields combines an array of micro-LEDs with an aligned array of micro-reflectors. The shaped, micro-reflective surfaces may be fabricated by laser etching a first sheet of glass. Micro-LEDs may include side-emitting LEDs. The shaped, micro-reflective surfaces of the micro-LED display emit collimated horizontal light useful for legal photometric requirements of stop lights, Center High Mounted Stop Lights (CHMSL), or Head-Up-Displays. Also, the lighting efficiency may be improved by using micro-LEDs coupled to micro-reflectors. Micro-LED displays may be unencapsulated, uncapsulated in a transparent coating, or they may be laminated in-between two sheets of glass to make a laminated, light-emitting window system. Laminated micro-LED displays may be used in windows of vehicles, including automobiles, trucks, motorcycles, farm equipment, boats, and airplanes.

### INTRODUCTION

This disclosure relates to micro-Light Emitting Diode (micro-LED) displays with micro-reflectors, for use with vehicle lighting applications.

Micro-LEDs are tiny, individual light-emitting diodes, typically less than 100 micrometers in size, that may be fabricated using advanced semiconductor manufacturing techniques. Micro-LED displays offer numerous advantages over prior-generation LED display systems, such as a higher brightness, improved color accuracy, greater energy efficiency, and other enhanced performance characteristics. These attributes make micro-LED displays ideal for automotive applications (e.g., in a vehicle's in-plane communication system), where visibility, clarity, and power efficiency are highly desirable.

Automobiles and airplanes use a variety of displays to provide information to the driver or pilot (e.g., instrument gauges, computer monitor screens, warning lights) and to communicate information to other drivers (e.g., rear brake lights, turn signals, Center Mounted High Stop Light (CMHSL)). Lighting systems typically have housings and/or large optical systems for tail lamps, front lamps, or CHSMLs, which are normally placed in the vehicle's body. In this way, space is required to package the lighting module, which adds more weight and assembly process time. Heads-Up Displays (HUDs) require light to be projected onto a transparent surface (glass or plastic), which typically requires the use of a separate light projector.

### SUMMARY

A method of fabricating micro-reflective surfaces disposed on a surface of, or disposed inside of, a window or mirror is disclosed. A micro-Light Emitting Diode (micro-LED) display for vehicle windows, mirrors, or windshields combines an array of micro-LEDs with an aligned array of micro-reflectors. The shaped, micro-reflective surfaces may be fabricated by laser etching a first sheet of glass. Micro-LEDs may include side-emitting micro-LEDs. The shaped, micro-reflective surfaces of the micro-LED display emit collimated horizontal light that is useful for any lighting requirement of a vehicle, including, but not limited to, legal photometric requirements of stop lights, Center High Mounted Stop Lights (CHMSL), Head-Up-Displays (HUDs), front lights, rear lights, side lights, side mirror lights, rear brake lights, truck bed lights, signaling lights, etc. Also, the lighting efficiency may be improved by using micro-LEDs optically coupled to micro-reflectors.

The micro-LED displays may be (1) open (unencapsulated), (2) encapsulated with a transparent coating, or (3) they may be laminated in-between two sheets of glass to make an integrated, light-emitting window system. The micro-LED displays may be used for side mirrors, rear-view mirrors, brake lights, sunroofs/moonroofs, windows, and windshields of different types of vehicles, including, but not limited to, automobiles, trucks, bicycles, motorcycles, farm equipment, construction equipment, boats, trains, and airplanes, etc.

In a first example, the micro-LED display unit includes a substrate, a micro-LED disposed on the substrate, and a micro-reflector disposed on the substrate adjacent to the micro-LED. The micro-LED is a side-emitting micro-LED. The micro-reflector includes a reflective surface facing the micro-LED. The micro-reflector has a height (H) above an upper surface of the substrate that is less than or equal to about 50 microns. A distance (d) between the micro-LED and the micro-reflector is less than or equal to about 0.5 mm.

In another example, the reflective surface is a flat surface that is oriented at an angle (q) with respect to a line that is perpendicular to the substrate. The angle (□) may range from about −30 degrees to about +30 degrees. A positive value of the angle (□) is measured in a clockwise direction.

In another example, the micro-reflector has a trapezoidal cross-sectional shape.

In another example, light emitted from the micro-LED display unit is emitted at a angle (q) with respect to the substrate, where q is less than or equal to about 30 degrees.

In another example, the micro-LED display unit further includes a layer of a transparent material covering and conformally encapsulating the micro-LED, the micro-reflector, and an upper surface of the substrate.

In another example, the substrate of the micro-LED display is transparent.

In another example, the upper surface of the substrate is reflective.

In another example, the micro-reflector and the substrate are made monolithically of a single material in an integrated fashion.

In another example, the substrate is curved. 2

In another example, a laminated, micro-Light Emitting Diode (micro-LED) display includes: a substrate having a frontside, a backside, and an array of micro-LEDs disposed on the substrate's frontside, a first sheet of transparent material having a first frontside and a first backside, and an array of recessed volumes disposed on the first backside of the first sheet. Each recessed volume includes one or more internal surfaces that define a geometrical shape of the recessed volume. A reflective coating is disposed on a rear portion of the one or more internal surfaces. A second sheet of transparent material is bonded and laminated to the substrate. Each micro-LED is aligned with, and disposed inside of, a matching recessed volume.

In another example, each recessed volume has a triangular, semi-circular, or oval shape.

In another example, each recessed volume has a curved triangular shape with two curved sidewalls.

In another example, each recessed volume has a trapezoidal or inverted trapezoidal shape.

In another example, each recessed volume has an inverted parabolic shape.

In another example, each recessed volume has a concave, reflecting surface and a convex, opposing surface.

In another example, the laminated, micro-LED display is integrated into a window, windshield, or mirror of a vehicle, wherein the vehicle is selected from the group consisting of automobiles, trucks, bicycles, motorcycles, farm equipment, construction equipment, boats, trains, and airplanes.

In another example, the laminated, micro-LED display is integrated as a Heads-Up Display (HUD) in a front windshield of the automobile.

In another example, the laminated, micro-LED display is configured as a Center High Mounted Stop Light (CHMSL) disposed in a rear windshield of the automobile.

In another example, a method of fabricating a laminated micro-Light Emitting Diode (micro-LED) display includes: (a) providing a first sheet of a first transparent material with a first frontside and a first backside, (b) fabricating a plurality of recessed volumes into the first backside of the first sheet, where each respective one of the recessed volumes has one or more internal surfaces that define a cross-sectional shape of each respective one of the recessed volumes, (c) depositing a reflective coating onto a rear portion of at least one of the one or more internal surface of each respective one of the recessed volumes, (d) providing a substrate with a second frontside, a second backside, and a plurality of micro-Light Emitting Diodes (micro-LEDs) disposed on the second frontside of the substrate, (e) aligning the plurality of micro-LEDs to the plurality of recessed volumes, where each respective one of the plurality of recessed volumes has a respective one of the plurality of micro-LEDs, (f) bonding the second frontside of the substrate to the first backside of the first sheet, thereby encapsulating each respective one of the plurality of micro-LEDs inside of each respective one of the plurality of the recessed volumes, (g) providing a second sheet of a second transparent material; and (h) adhesively bonding and laminating the second sheet to the second backside of the substrate.

In another example, the reflective rear portion of at least one of the one or more internal surfaces has less than or equal to about 50% of a total surface area of each respective one of the plurality of recessed volumes.

### BRIEF DESCRIPTION OF THE DRAWINGS

FIG. 1A shows a schematic cross-sectional, elevation view of an example of an open (unencapsulated) micro-Light Emitting Diode (micro-LED) display unit, according to the present disclosure.

FIG. 1B shows a schematic cross-sectional, elevation view of the example shown in FIG. 1A of an open (unencapsulated) micro-LED display unit, according to the present disclosure.

FIG. 2 shows a schematic cross-sectional, elevation view of an example of an open (unencapsulated) micro-LED display, according to the present disclosure.

FIG. 3 shows a schematic cross-sectional, elevation view of an example of an encapsulated micro-LED display unit, according to the present disclosure.

FIG. 4 shows a schematic cross-sectional, elevation view of an example of an encapsulated micro-LED display, according to the present disclosure.

FIG. 5 shows a schematic cross-sectional, elevation view of an example of an open (unencapsulated) micro-LED display unit, according to the present disclosure.

FIG. 6 shows a schematic cross-sectional, elevation view of an example of an open (unencapsulated) micro-LED display, according to the present disclosure.

FIG. 7A shows a schematic cross-sectional, elevation view of an example of a first process step for fabricating an encapsulated micro-LED display, according to the present disclosure.

FIG. 7B shows a schematic cross-sectional, elevation view of an example of a second process step for fabricating an encapsulated micro-LED display, according to the present disclosure.

FIG. 7C shows a schematic cross-sectional, elevation view of an example of a third process step for fabricating an encapsulated micro-LED display, according to the present disclosure.

FIG. 7D shows a schematic cross-sectional, elevation view of an example of a fourth process step for fabricating an encapsulated micro-LED display, according to the present disclosure.

FIG. 7E shows a schematic cross-sectional, elevation view of an example of a fifth process step for fabricating an encapsulated micro-LED display, according to the present disclosure.

FIG. 7F shows a schematic cross-sectional, elevation view of an example of a sixth process step for fabricating an encapsulated micro-LED display, according to the present disclosure.

FIG. 8A shows a schematic cross-sectional, elevation view of an example of an encapsulated micro-LED display, according to the present disclosure.

FIG. 8B shows a schematic cross-sectional, elevation view of an example of an encapsulated micro-LED display, according to the present disclosure.

FIG. 8C shows a schematic cross-sectional, elevation view of an example of an encapsulated micro-LED display, according to the present disclosure.

FIG. 8D shows a schematic cross-sectional, elevation view of an example of an encapsulated micro-LED display, according to the present disclosure.

FIG. 8E shows a schematic cross-sectional, elevation view of an example of an encapsulated micro-LED display, according to the present disclosure.

FIG. 8F shows a schematic cross-sectional, elevation view of an example of an encapsulated micro-LED display, according to the present disclosure.

FIG. 8G shows a schematic cross-sectional, elevation view of an example of an encapsulated micro-LED display, according to the present disclosure.

FIG. 9 shows a schematic elevation view of an example of an automobile with a pair of micro-LED displays, according to the present disclosure.

FIG. 10 shows an example of a process flow chart illustrating steps for fabricating a micro-LED display, according to the present disclosure.

FIG. 11 shows a schematic cross-sectional, elevation view of an example of an encapsulated micro-LED display unit, according to the present disclosure.

FIG. 12 shows a schematic cross-sectional, elevation view of an example of an encapsulated micro-LED display unit, according to the present disclosure.

FIG. 13 shows a schematic cross-sectional, elevation view of an example of an open (unencapsulated) micro-LED display unit, according to the present disclosure.

FIG. 14 shows a schematic cross-sectional, elevation view of an example of an encapsulated micro-LED display unit, according to the present disclosure.

### DETAILED DESCRIPTION OF THE DISCLOSURE

A method is disclosed for fabricating shaped, micro-reflective surfaces disposed on the surface of, or disposed inside of, transparent windows or windshields. A micro-Light Emitting Diode (micro-LED) display for vehicle windows combines an array of micro-LEDs with an aligned array of micro-reflectors. The shaped, micro-reflective surfaces may be fabricated by using laser etching technology. The array of shaped, micro-reflective surfaces in micro-LED displays create optimized, collimated beam patterns for legal photometric requirements of stop lights or Center High Mounted Stop Lights (CHMSL). Also, the lighting efficiency may be improved by using the arrays of micro-LEDs and micro-reflector structures. The micro-LED display may be positioned and bonded in-between a pair of laminated, transparent sheets (which may be glass or plastic), to make an integrated, light-emitting, laminated window or windshield system.

The term “window” broadly includes windows, mirrors, and windshields. The light-emitting window, which may be a Heads-Up Display (HUD), may be a part of an automobile, motorcycle, boat, airplane, or jet. The micro-LED display disclosed herein may be used in side-mirrors, rear window mirrors, sunroofs/moonroofs in automobiles, trucks, farm equipment, motorcycles, construction equipment, etc. In the Figures, reflecting surfaces are illustrated as a thick, black line. The word “open” means “unencapsulated” herein. The phrases “side-firing” and “side-emitting” are interchangeable, as they refer to LEDs or micro-LEDs. The phrases “micro-reflectors” and “micro-reflecting structures” are interchangeable. The term “shallow” as it refers to some examples of an angle, q, means that q is less than or equal to about 30 degrees. The term “about” means that the referenced value is +/−5% of the referenced value. The phrase “unidirectional, side-firing micro-LED” means that light is emitted from a single side of the micro-LED.

Reflecting surfaces on the micro-reflectors may comprise polished surfaces and/or one or more coatings of a deposited reflective material and/or a dielectric stack comprising, for example, silver, gold, copper, silicon dioxide (SiO₂), silicon nitride (Si₃N₄), polyimide, benzo cyclobutene (BCB), spin-on glass (SOG), aluminum oxide (Al₂O₃), hafnium oxide (HfO₂), and/or combinations thereof). Lithography and masking may be combined with physical or chemical vapor deposition, sputter coating, etc. to selectively deposit reflective coatings on selected surfaces and not elsewhere. Alternatively, reflective coatings may be initially applied to the entire surface, and then selectively removed from unwanted (non-reflective) surfaces using laser etching or a similar removal process.

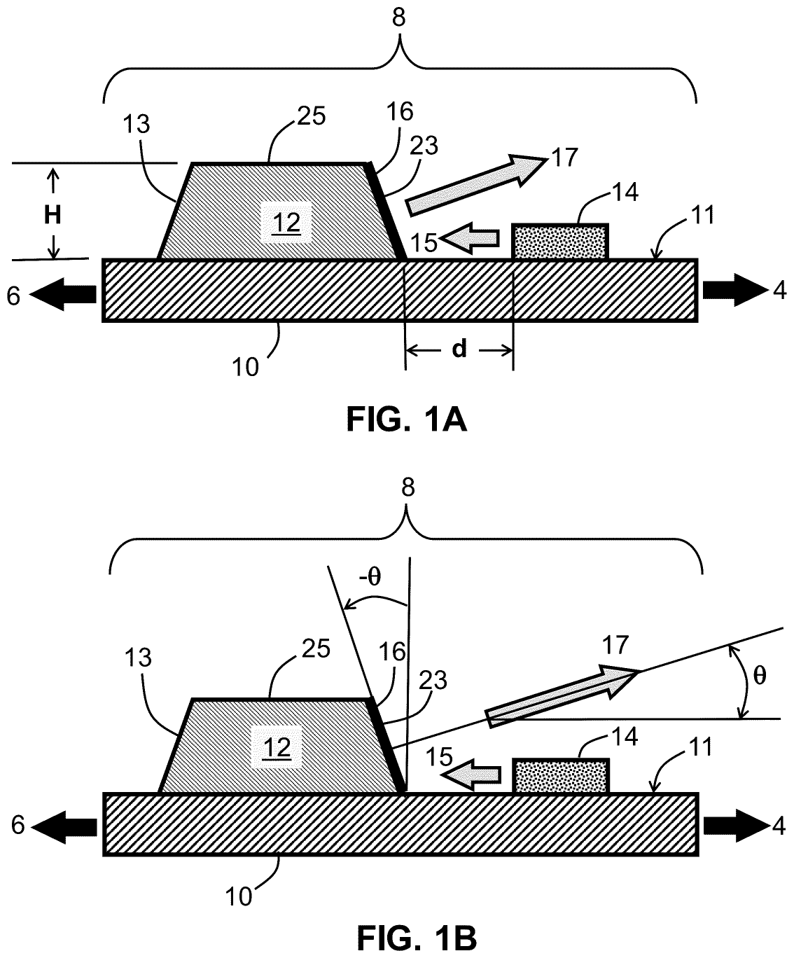

FIG. 1A shows a schematic, cross-sectional, elevation view of an example of an open (unencapsulated) micro-LED display unit 8, according to the present disclosure. Micro-LED display unit 8 comprises a substrate 10 with a micro-reflector 12 disposed on a frontside of substrate 10, and a micro-Light Emitting Diode (micro-LED) 14 also disposed on the frontside of substrate 10, positioned next to and adjacent to micro-reflector 12. In some embodiments, upper surface 11 of substrate 10 may be reflective or non-reflective (as shown in this example). Micro-reflector 12, which has a trapezoidal shape in this example, has at least one sloped, reflective front face 23 with a reflective surface 16 that is angled backwards, (i.e., counterclockwise) at an angle (q) (see FIG. 1B). Reflective front surface 16 faces toward micro-LED 14. Opposing, rear face 13 of micro-reflector 12 may be reflective or non-reflective (as shown in this example). Upper (topmost) surface 25 of micro-reflector 12 may not be coated with a reflective coating. Substrate 10 may be made of glass, plastic, polymer, polycrystalline silicon, silicon carbide, silicon nitride, alumina, zirconia, sapphire, semiconductors, dielectrics, or an electrically insulating material. Substrate 10 may be flat or curved. Substrate 10 may be transparent, translucent, or opaque. Micro-reflector 12 may be made of glass or a polymer material, such as: polycarbonate (PC) or polymethyl methacrylate (PMMA). Micro-reflector 12 and substrate 10 may be made monolithically of a single material in an integrated fashion.

Referring still to FIG. 1A, micro-LED 14 is disposed on substrate 10 at a distance (d), from the reflective surface 16 of micro-reflector 12. In some embodiments, d is less than or equal to about 0.05 mm. In some embodiments, d is less than or equal to about 0.1 mm. In some embodiments, d is less than or equal to about 0.5 mm. Micro-reflector 12 has a height (H) above the upper surface 11 of substrate 8. In some embodiments, H is less than or equal to about 20 microns. In some embodiments, H is less than or equal to about 30 microns. In some embodiments, H is less than or equal to about 40 microns. In some embodiments, H is less than or equal to about 50 microns.

Referring still to FIG. 1A, a forward direction 4 and a rearward direction 6 of micro-LED display 8 are indicated. Reflective front face 16 is located on the forward-facing side surface 23 of micro-reflector 12 (i.e., facing in the forward direction 4). Micro-LED 14 may be a side-emitting LED that emits rearward light ray 15 sideways (e.g., horizontal) direction in the rearward direction 6, with only a small amount (or none) of light rays being emitted vertically. Alternatively, micro-LED 14 may be a unidirectional, side-emitting micro-LED, emitting light primarily in the rearward direction 6 as rearward light ray 15. Rearward light ray 15 reflects from reflective surface 16 and then is projected in primarily a forward direction 4 as forward light ray 17 at an angle, q, with respect to the upper surface 11 of substrate 10. Because of the unique geometrical arrangement of optical and light-emitting elements in FIG. 1A, forward light ray 17 is primarily projected in forward direction 4 as a collimated, narrow beam of light having a vertical thickness on the order of H, with a relatively narrow range of angular dispersion. Very little light is emitted vertically from micro-LED display unit 8 because of its unique optical configuration. The intensity of light emitted by micro-LED display unit 8 may be less than or equal to about 1000 lumens.

FIG. 1B shows a schematic cross-sectional, elevation view of the example shown in FIG. 1A of an open (unencapsulated) micro-LED display unit 8, according to the present disclosure. In some embodiments, q is less than or equal to about 30 degrees. In other embodiments, q is less than or equal to about 25 degrees. In other embodiments, q is less than or equal to about 20 degrees. In other embodiments, q is less than or equal to about 15 degrees. In other embodiments, q is less than or equal to about 10 degrees. In other embodiments, q is less than or equal to about 5 degrees. Opposing rear face 13 may be sloped at the same angle, q, as front reflective face 16. Alternatively, opposing rear face 13 may be sloped at a different angle as front reflective face 23, e.g., perpendicular to substrate 10.

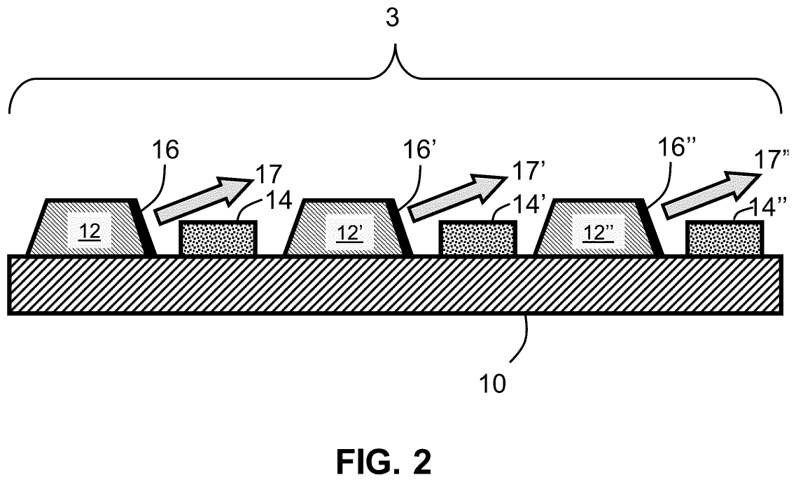

FIG. 2 shows a schematic cross-sectional, elevation view of an example of an open (unencapsulated) micro-LED display 3, according to the present disclosure. Open micro-LED display 3 comprises an array of multiple micro-reflectors 12, 12′, 12″, etc. disposed on substrate 10 and an aligned array of multiple micro-LEDs 14, 14′, 14″, etc., is also disposed on substrate 10. The array of micro-LEDs 14, 14′, 14″ is aligned and positioned in-between adjacent micro-reflectors 12, 12′, 12″, etc. Forward-projected light rays 17, 17′, 17″, etc. emit light in a predominantly forward direction 4 at a shallow angle, q (See FIG. 1B). The arrays of micro-LEDs 14, 14′, 14″, etc. and micro-reflectors 12, 12′, 12″, etc. may be positioned on a square, rectangular, or circular grid (not shown), when viewed from above substrate 10. While only three micro-LED display units are shown for ease of illustration and discussion, it should be understood that a micro-LED display 3 may include any number of individual micro-LED display units (as illustrated in FIG. 1A).

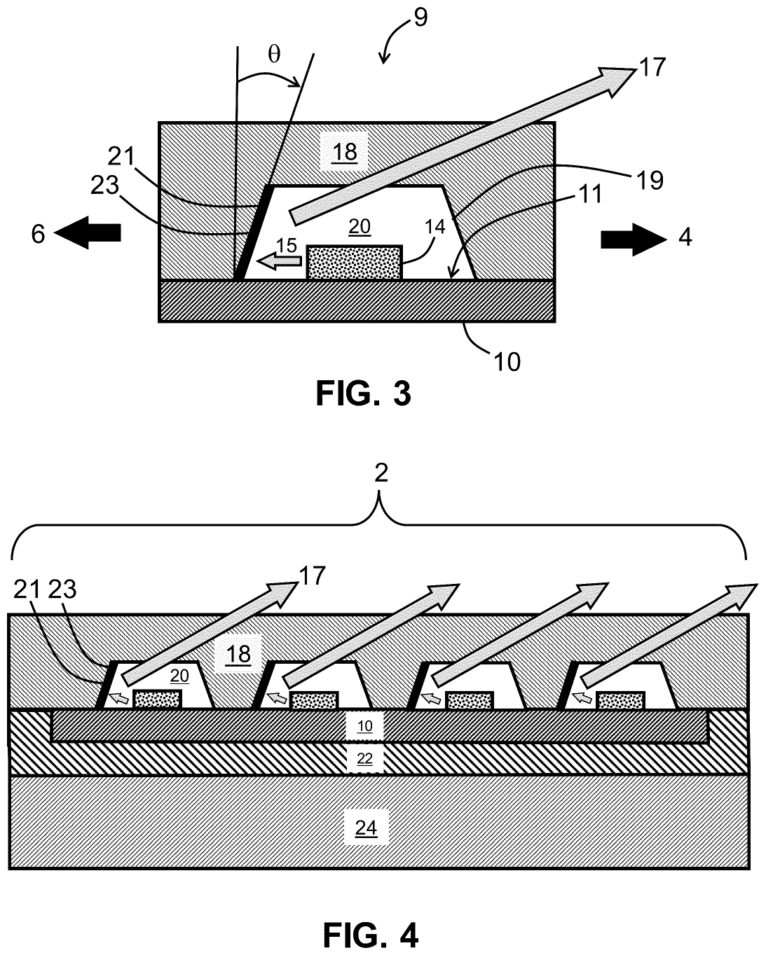

FIG. 3 shows a schematic cross-sectional, elevation view of an example of an encapsulated micro-LED display unit 9, according to the present disclosure. Encapsulated micro-LED display unit 9 comprises a substrate 10 with a transparent cap 18 bonded to a frontside of substrate 10. A micro-Light Emitting Diode (micro-LED) 14 is also disposed on the frontside of substrate 10. Transparent cap 18 has a recessed volume (pocket) 20, which has a trapezoidal shape in this example. Micro-LED 14 is positioned underneath transparent cap 18, and transparent cap 18 encapsulates and surrounds micro-LED 14. Sloped, internal rear face 21 is reflective and is angled clockwise at a shallow angle (q). The opposing, sloped internal front face 19 of transparent cap 18 is non-reflective. Transparent cap 18 may be made of any transparent material, including glass, plastic, polymer, polycarbonate (PC) material, acrylic materials such as polymethyl methacrylate (PMMA), thermoplastics such as thermoplastic polyurethane (TPU), glass-ceramic materials, such as soda-lime-silica glass-ceramics, aluminosilicate glass-ceramics, lithium aluminosilicate glass-ceramics, spinel glass-ceramics, and beta-quartz glass-ceramics, sapphire, and/or combinations thereof. Substrate 10 may be made of glass, plastic, polymer, an electrically insulating material, polycarbonate (PC) material, acrylic materials such as polymethyl methacrylate (PMMA), thermoplastics such as thermoplastic polyurethane (TPU), glass-ceramic materials, such as soda-lime-silica glass-ceramics, aluminosilicate glass-ceramics, lithium aluminosilicate glass-ceramics, spinel glass-ceramics, and beta-quartz glass-ceramics, sapphire, and/or combinations thereof. Transparent cap 18 and/or substrate 10 may be flat or curved. Substrate 10 may be transparent, translucent, or opaque. Upper surface 11 of substrate 10 may be reflective or non-reflective.

Referring still to FIG. 3, a forward direction 4 and a rearward direction 6 of encapsulated micro-LED display unit 9 are illustrated. Reflective rear internal face 21 is located on the forward-facing back side 21 of transparent cap 18 (i.e., facing towards the forward direction 4). Micro-LED 14 may be a directional, side-emitting micro-LED that emits rearward light ray 15 a sideways (horizontal) direction in the rearward direction 6, with a small amount (or none) of light rays being emitted vertically or in the forward direction 4. Rearward light ray 15 reflects from reflective surface 21 and then is projected primarily in a forward direction 4 as forward light ray 17 at a shallow angle, q, with respect to the upper surface 11 of substrate 10. Because of this geometrical arrangement of optical elements, a majority of the forward light rays 17, 17′, etc. are emitted in the forward direction 4 as a collimated beam of light having a vertical thickness on the order of H, and a relatively narrow amount of angular dispersion. Very little light is emitted vertically from encapsulated micro-LED display unit 9, because of this unique optical configuration. The intensity of light emitted by encapsulated micro-LED display unit 9 may be less than or equal to about 1000 lumens.

Referring still to FIG. 3, in some embodiments, q is less than or equal to about 30 degrees. In other embodiments, q is less than or equal to about 25 degrees. In other embodiments, q is less than or equal to about 20 degrees. In other embodiments, q is less than or equal to about 15 degrees. In other embodiments, q is less than or equal to about 10 degrees. In other embodiments, q is less than or equal to about 5 degrees.

FIG. 4 shows a schematic cross-sectional, elevation view of an example of an encapsulated micro-LED display 2, according to the present disclosure. Encapsulated micro-LED display 2 comprises an upper, transparent first sheet 18 with an array of trapezoidal recessed volumes 20, 20′, 20″, etc. and an array of multiple micro-reflecting faces 21, 21′, 21″, etc. disposed on forward-facing, rear surfaces 21, 21′, 21″, etc. of each respective recessed volumes 20, 20′, 20″, etc. An array of multiple micro-LEDs 14, 14′, 14″, etc., is also disposed on substrate 10. The array of micro-LEDs 14, 14′, 14″ is aligned and positioned inside of each respective of the array of recessed volumes 20, 20′, 20″, etc. In other words, each individual micro-LED 14 is enclosed within a matching, recessed volume 20. Transparent cap 18 is bonded to substrate 10.

Referring still to FIG. 4, forward-projected light rays 17, 17′, 17″, etc. emit light in a predominantly forward direction 4 at an angle (q) with respect to a line that is oriented perpendicular to substrate 10. See FIG. 1B. The arrays of micro-LEDs 14 and micro-reflecting faces 21 may be positioned and arranged on a square, rectangular, or circular grid (not shown), when viewed from above substrate 10. Recessed volumes 20, 20′, 20″, etc. may be fabricated by laser etching first sheet 18. First sheet 18, with bonded substrate 10, is then laminated and bonded with adhesive 22 to a second sheet 24 (which may be transparent or not transparent). Adhesive 22 may comprise polyvinyl butyral (PVB) or an equivalent adhesive. The two laminated sheets 18 and 24 may be bagged, heated, and compressed together under pressure and elevated temperature in an autoclave.

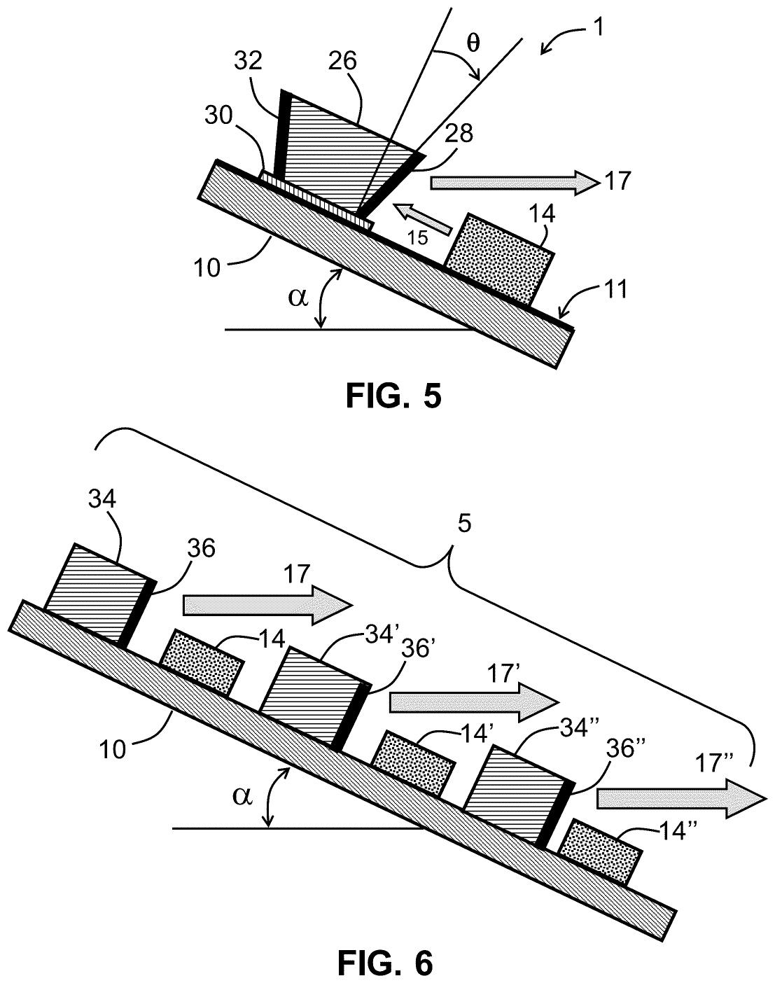

FIG. 5 shows a schematic cross-sectional, elevation view of an example of an open (unencapsulated) micro-LED display unit 1, according to the present disclosure. Micro-LED display unit 1 comprises a substrate 10 with a micro-reflector 12 disposed on a frontside of substrate 10, and a micro-Light Emitting Diode (micro-LED) 14 also disposed on the frontside of substrate 10, positioned closely adjacent to micro-reflector 26. Micro-reflector 26 may be bonded to substrate 10 with adhesive 30, such as polyvinyl butyral (PVB). Upper surface 11 of substrate 10 may be reflective or non-reflective. Micro-reflector 26, which has an inverted trapezoidal shape, has at least one sloped, reflective front face 28 that is angled clockwise at an angle=q. Opposing, sloped rear face 32 of micro-reflector 26 may be reflective (as shown in this example) or non-reflective. Substrate 10 may be made of glass, plastic, polymer, or an electrically insulating material. Substrate 10 may be flat or curved, and it may be transparent, translucent, or opaque. Substrate 10 may be angled at a different angle (a) where a may be selected by matching it a slope of a rear window in an automobile (see FIG. 9). In some embodiments, q may approximately be equal to a. In other embodiments, q<a. In some embodiments, q, is chosen so that the direction of forward light ray 17 is approximately horizontal with respect to the ground (e.g., for a Center High Mounted Stop Light (CHMSL) application or for a Heads-Up-Display (HUD) application. See, for example, FIG. 9.

FIG. 6 shows a schematic cross-sectional, elevation view of an example of an open (unencapsulated) micro-LED display 5, according to the present disclosure. Open micro-LED display 5 comprises an array of multiple micro-reflectors 34, 34′, 34″, etc. disposed on substrate 10. An aligned array of multiple micro-LEDs 14, 14′, 14″, etc., is also disposed on substrate 10. The array of micro-LEDs 14, 14′, 14″, etc. is aligned and positioned in-between adjacent micro-reflectors 34, 34′, 34″, etc. In this example, micro-reflectors 34, 34′, 34″, etc. may be squares (cubes) with reflective faces 36, 36′, and 36″, etc., respectively that are perpendicular to substrate 10 (i.e., q=0 degrees). Forward-projected light rays 17, 17′, 17″, etc. emit light in a predominantly horizontal forward direction. The arrays of micro-LEDs 14, 14′, 14″, etc. and micro-reflectors 34, 34′, 34″, etc. may be positioned on a square, rectangular, or circular grid (not shown), when viewed from above substrate 10.

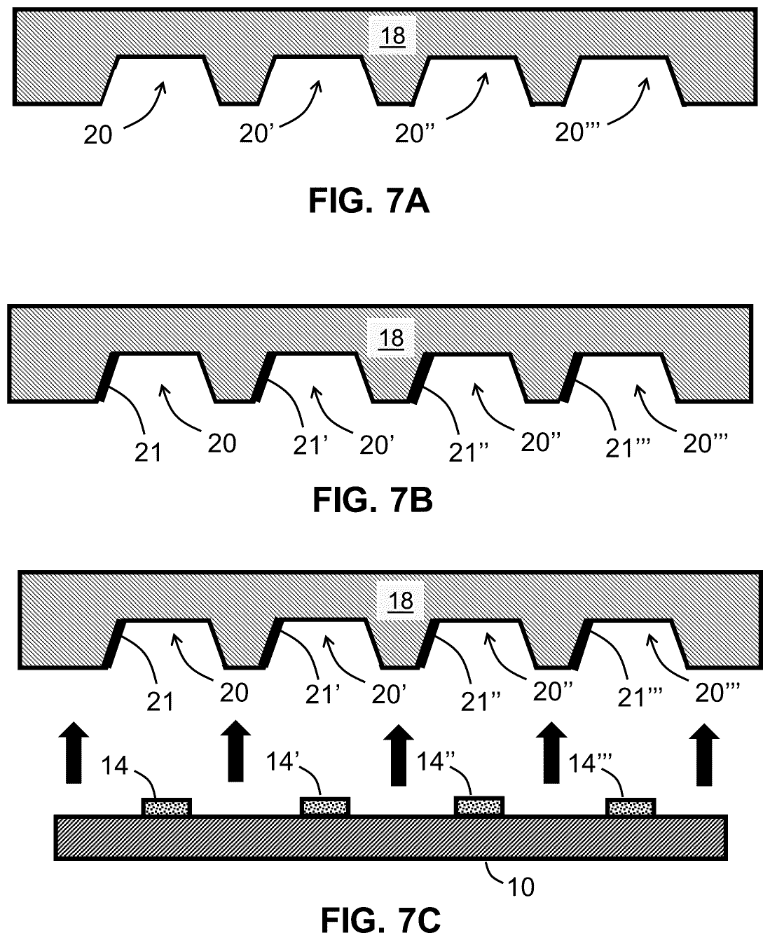

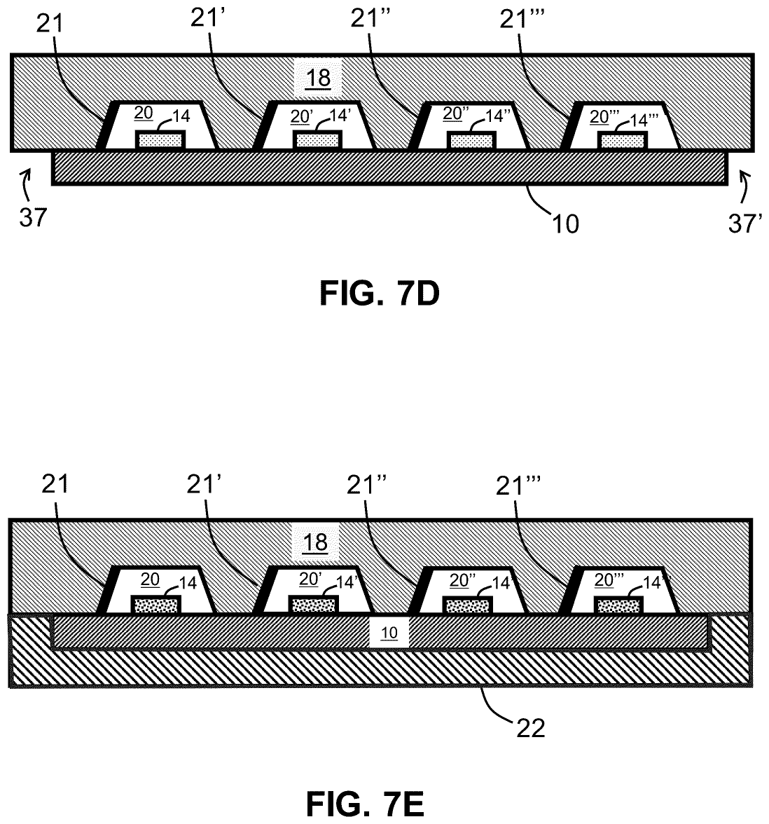

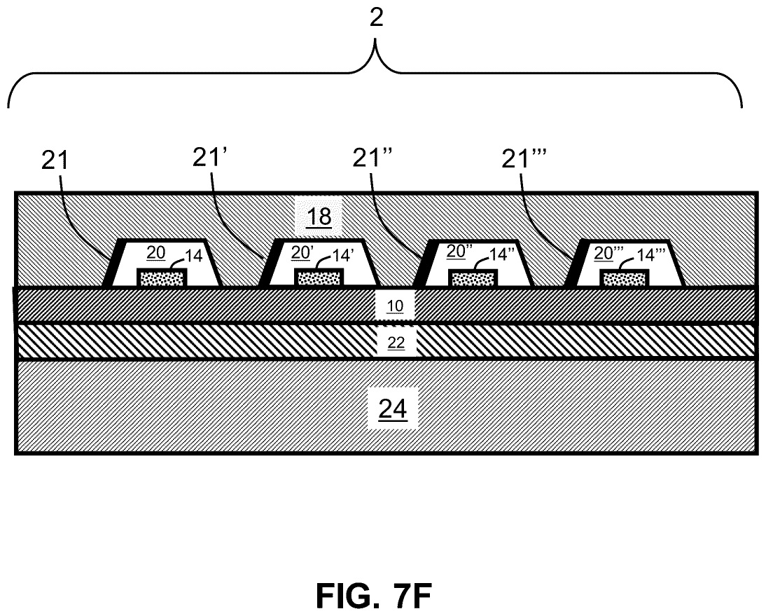

FIG. 7A shows a schematic cross-sectional, elevation view of an example of first process step for fabricating an encapsulated micro-LED display 2, according to the present disclosure. The first step comprises providing a first sheet 18 of transparent material, comprising an upper frontside and a lower backside, and then fabricating a plurality of identical, recessed volumes 20, 20′, 20″, 20″′, etc. by selectively laser etching or chemically removing material from the backside of first sheet 18. Each recessed volume 20, 20′, 20″, 20″′, etc. comprises one or more internal surfaces (not numbered) that define an internal shape of each recessed volume. In this example, each recessed volume 20, 20′, 20″, 20″′, etc. has a trapezoidal shape.

FIG. 7B shows a schematic cross-sectional, elevation view of an example of a second process step for fabricating an encapsulated micro-LED display 2, according to the present disclosure. The second step comprises depositing a reflective coating 21, 21′, 21″, 21″′, etc. onto a rear portion of an internal surface of each recessed volume 20, 20′, 20″, 20″′, etc.

FIG. 7C shows a schematic cross-sectional, elevation view of an example of a third process step for fabricating an encapsulated micro-LED display 2, according to the present disclosure. The third step comprises providing a substrate 10 comprising a plurality of micro-LEDs 14, 14′, 14″, 14″′, etc. disposed in an array on a frontside of substrate 10, wherein substrate 10 has a backside.

FIG. 7D shows a schematic cross-sectional, elevation view of an example of a fourth process step for fabricating an encapsulated micro-LED display 2, according to the present disclosure. The fourth step then comprises aligning the micro-LEDs 14, 14′, 14″, 14″′, etc. to the recessed volumes 20, 20′, 20″, 20″′, etc. and bonding substrate 10 to the backside of first sheet 18, thereby encapsulating the micro-LEDS 14, 14′, 14″, 14″′, etc. in the recessed volumes 20, 20′, 20″, 20″′, etc. of transparent first sheet 18.

FIG. 7E shows a schematic cross-sectional, elevation view of an example of a fifth process step for fabricating an encapsulated micro-LED display 2, according to the present disclosure. The fifth step comprises applying a layer of adhesive 22 to the backside of substrate 10. Adhesive 22 may comprise polyvinyl butyral (PVB) or equivalent adhesive.

FIG. 7F shows a schematic cross-sectional, elevation view of an example of a sixth process step for fabricating an encapsulated micro-LED display 2, according to the present disclosure. The sixth step comprises adhesively bonding a second sheet 24 to both the substrate 10 and the backside of first sheet 18. This final, sixth step includes vacuum bagging the assembled sheets and autoclaving the bagged assembly in a heated pressure vessel under external pressure. This completes the encapsulation, bonding, and lamination process.

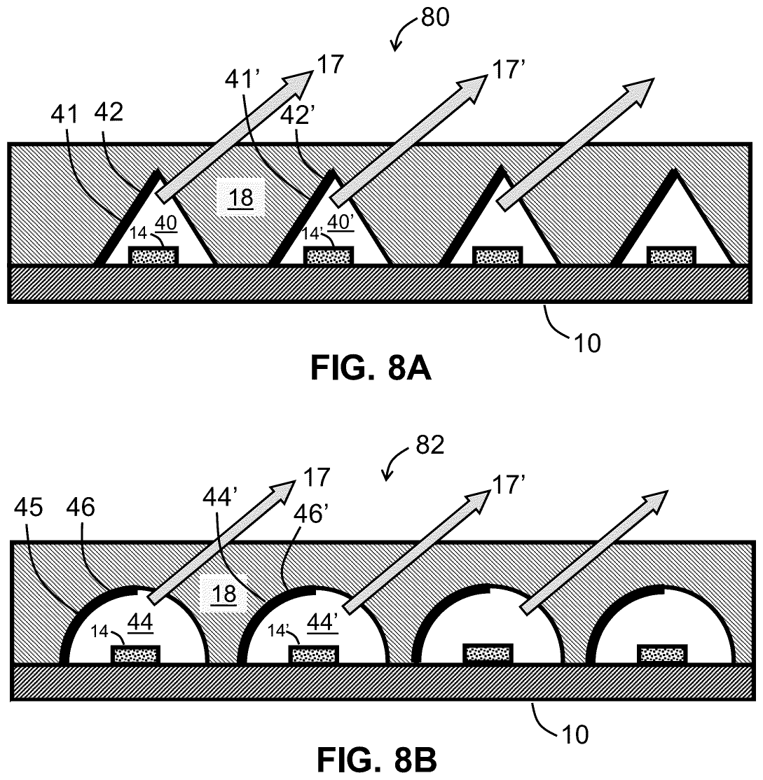

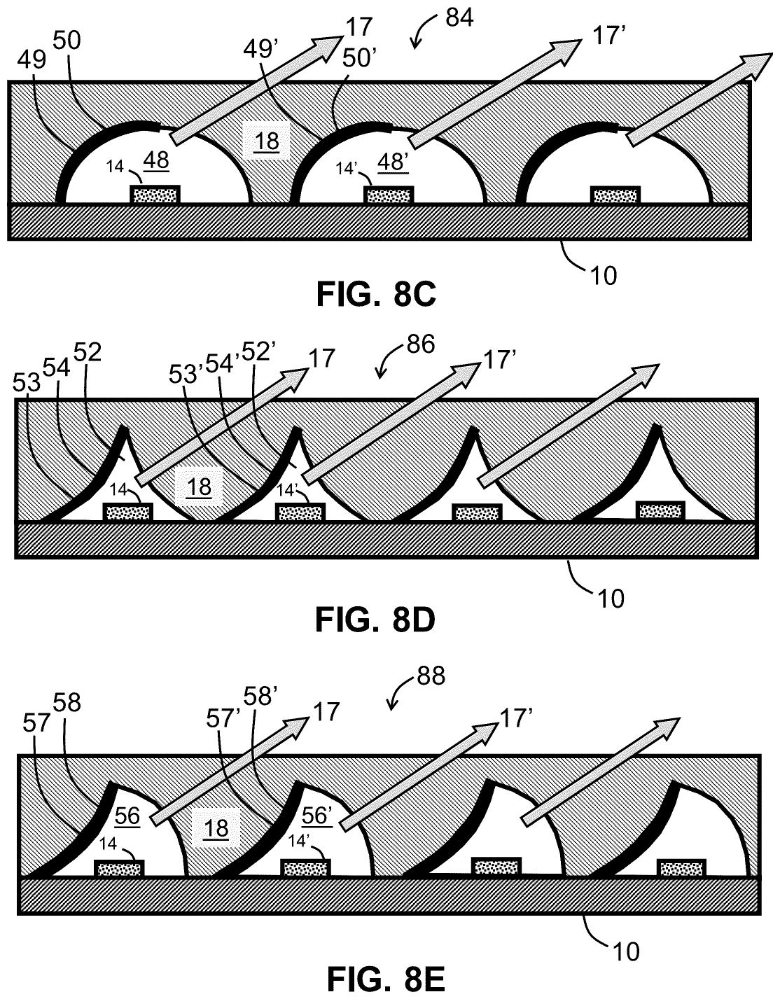

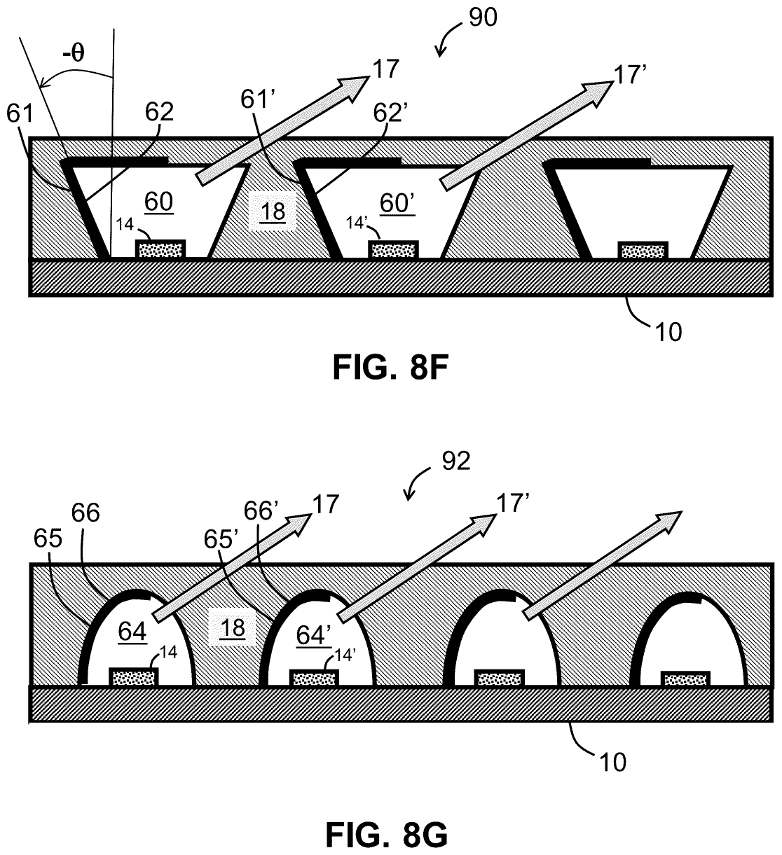

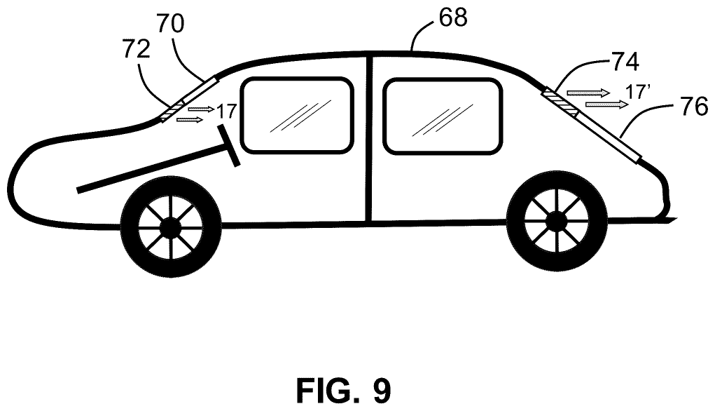

FIG. 8A shows a schematic cross-sectional, elevation view of an example of an encapsulated micro-LED display 80, according to the present disclosure. An array of micro-LEDs 14, 14′, etc. are encapsulated within triangle-shaped recessed volumes 40, 40′, respectively, of first transparent sheet 18. Reflective surfaces 42, 42′, etc. are disposed on the rear internal surfaces 41, 41′, etc. of recessed volumes 40, 40′, etc., respectively. Reflective surfaces 42, 42′, etc. cover about 50% of the internal surface area of each recessed volume 40, 40′, etc., respectively.

FIG. 8B shows a schematic cross-sectional, elevation view of an example of an encapsulated micro-LED display 82, according to the present disclosure. An array of micro-LEDs 14, 14′, etc. are encapsulated within semicircle-shaped recessed volumes 44, 44′, etc., respectively, of first transparent sheet 18. Reflective surfaces 46, 46′, etc. are disposed on the rear internal surfaces 45, 45′, etc. of recessed volumes 44, 44′, etc., respectively. Reflective surfaces 46, 46′, etc. cover about 50% of the internal surface area of each recessed volume 40, 40′, etc., respectively.

FIG. 8C shows a schematic cross-sectional, elevation view of an example of an encapsulated micro-LED display 84, according to the present disclosure. An array of micro-LEDs 14, 14′, etc. are encapsulated within oval-shaped recessed volumes 48, 48′, etc., respectively, of first transparent sheet 18. Reflective surfaces 50, 50′, etc. are disposed on the rear internal surfaces 49, 49′, etc. of recessed volumes 48, 48′, respectively. Reflective surfaces 50, 50′, etc. cover about 50% of the internal surface area of each recessed volume 48, 48′, etc., respectively.

FIG. 8D shows a schematic cross-sectional, elevation view of an example of an encapsulated micro-LED display 86, according to the present disclosure. An array of micro-LEDs 14, 14′, etc. are encapsulated within curved-triangle-shaped recessed volumes 52, 52′, etc., respectively, of first transparent sheet 18. Reflective surfaces 54, 54′, etc. are disposed on the rear internal surfaces 53, 53′, etc. of recessed volumes 52, 52′, etc. respectively. Reflective surfaces 54, 54′, etc. cover about 50% of the internal surface area of each recessed volume 52, 52′, etc., respectively.

FIG. 8E shows a schematic cross-sectional, elevation view of an example of an encapsulated micro-LED display 88, according to the present disclosure. An array of micro-LEDs 14, 14′, etc. are encapsulated within asymmetric, concave-convex-shaped recessed volumes 56, 56′, etc. respectively, of first transparent sheet 18. Reflective surfaces 58, 58′, etc. are disposed on the rear internal surfaces 57, 57′, etc. of recessed volumes 56, 56′, etc., respectively. Reflective surfaces 58, 58′, etc. cover about 50% of the internal surface area of each recessed volume 56, 56′, etc., respectively.

FIG. 8F shows a schematic cross-sectional, elevation view of an example of an encapsulated micro-LED display 90, according to the present disclosure. An array of micro-LEDs 14, 14′, etc. are encapsulated within inverted-trapezoid shaped recessed volumes 60, 60′, etc., respectively, of first transparent sheet 18. Reflective surfaces 62, 62′, etc. are disposed on the rear internal surfaces 61, 61′, etc. of recessed volumes 60, 60′, etc., respectively. Reflective surfaces 62, 62′, etc. cover about 50% of the internal surface area of each recessed volume 60, 60′, etc., respectively.

FIG. 8G shows a schematic cross-sectional, elevation view of an example of an encapsulated micro-LED display 92, according to the present disclosure. An array of micro-LEDs 14, 14′, etc. are encapsulated within inverted parabola shaped recessed volumes 64, 64′, etc., respectively, of first transparent sheet 18. Reflective surfaces 66, 66′, etc. are disposed on the rear internal surfaces 65, 65′, etc. of recessed volumes 64, 64′, etc., respectively. Reflective surfaces 66, 66′, etc. cover about 50% of the internal surface area of each recessed volume 64, 64′, etc., respectively.

FIG. 9 shows a schematic elevation view of an example of an automobile 68 with a pair of micro-LED displays 72 and 74, according to the present disclosure. The front micro-LED display 72 is located inside of the front windshield 70 of automobile 68 and serves as a Heads-Up-Display (HUD). Light rays 17 are emitted horizontally from the micro-LED display 72 towards the driver's head (not shown). The rear micro-LED display 74 is located inside of the rear windshield 70 of automobile 68 and serves as a Center Mounted High Stop Light (CMHSL). Light rays 17′ are emitted horizontally from the micro-LED display 74 towards the head of the driver following automobile 68 (not shown).

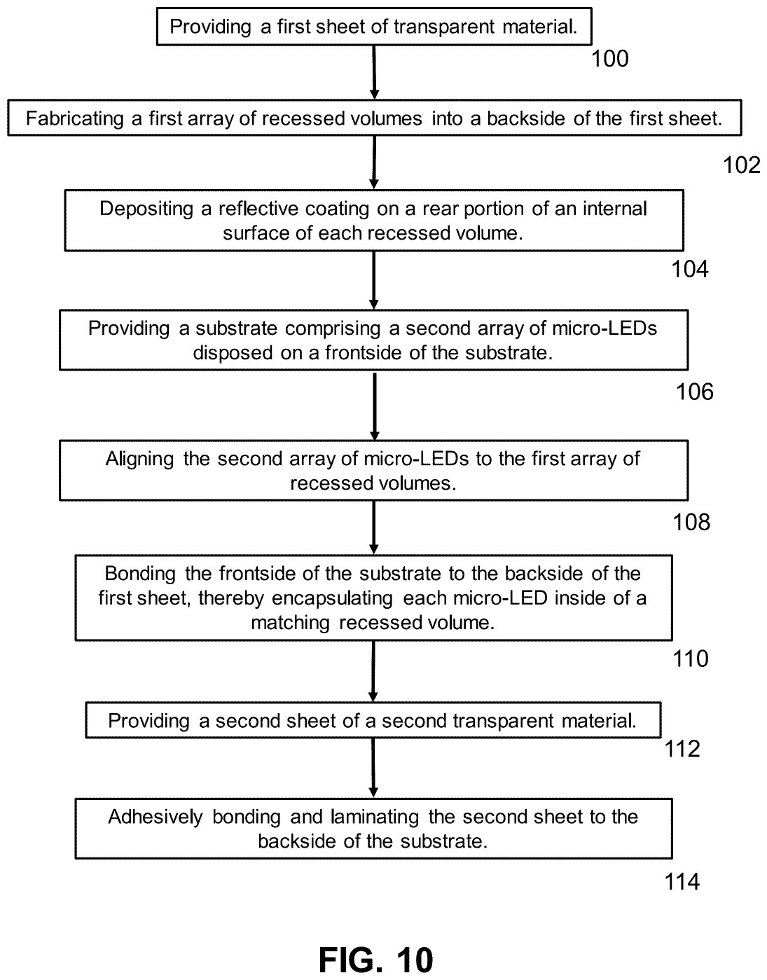

FIG. 10 shows an example of a process flow chart illustrating examples of process steps for fabricating a micro-LED display, according to the present disclosure. Step 100 includes providing a first sheet of transparent material. Step 102 includes fabricating (e.g., laser etching) a first array of recessed volumes into a backside of the first sheet. Step 104 includes depositing a reflective coating on a rear portion of an internal surface of each recessed volume. Step 106 includes providing a substrate comprising a second array of micro-LEDs disposed on a frontside of the substrate. Step 108 includes aligning the second array of micro-LEDs to the first array of recessed volumes. Step 110 includes bonding the substrate to the backside of the first sheet, thereby encapsulating each micro-LEDs inside of a matching recessed volume of the transparent first sheet. Step 112 includes providing a second sheet of a second transparent material. Step 114 includes adhesively bonding and laminating the second sheet to both the backside of the substrate and to the backside of the first sheet.

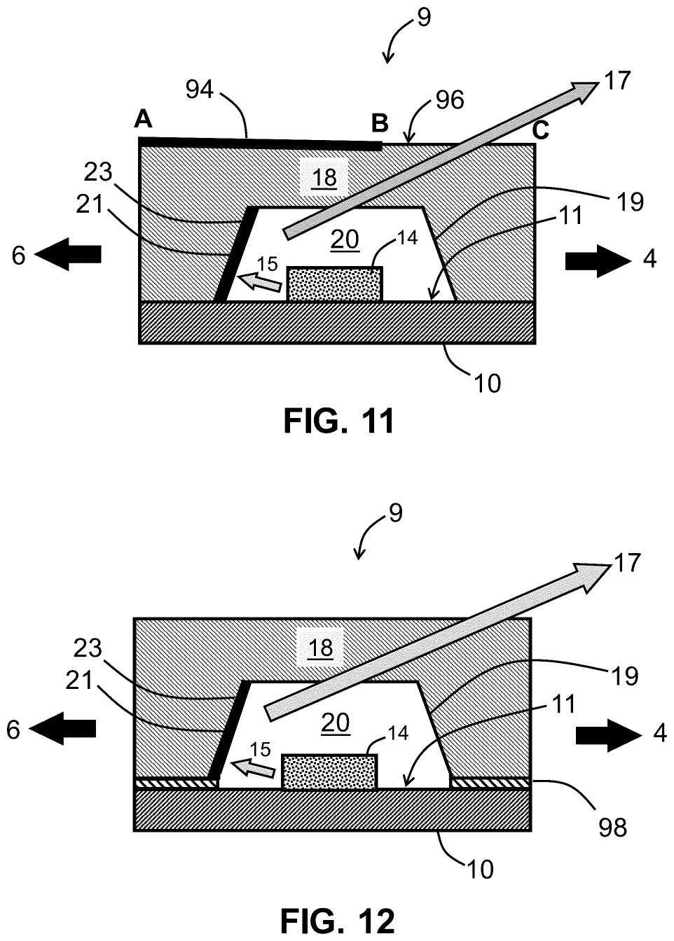

FIG. 11 shows a schematic cross-sectional, elevation view of an example of an encapsulated micro-LED display unit 9, according to the present disclosure. This illustration is identical to FIG. 3, with the exception being that an opaque coating 94 has been applied to a rear upper portion (i.e., between points “A” and “B”) of the upper surface 96 of transparent first sheet 18, to prevent stray light from being emitted though the covered portion 94 of first sheet 18. The remaining portion (i.e., between points “B” and “C”) of the upper surface 96 of first sheet 18 is uncoated and may allow light to be transmitted through that portion of transparent first sheet 18.

FIG. 12 shows a schematic cross-sectional, elevation view of an example of an encapsulated micro-LED display unit, according to the present disclosure. In this embodiment, transparent cap 18 may be bonded adhesively to substrate 10 with an optically-clear adhesive 98, which may comprise polyvinyl butyral (PVB).

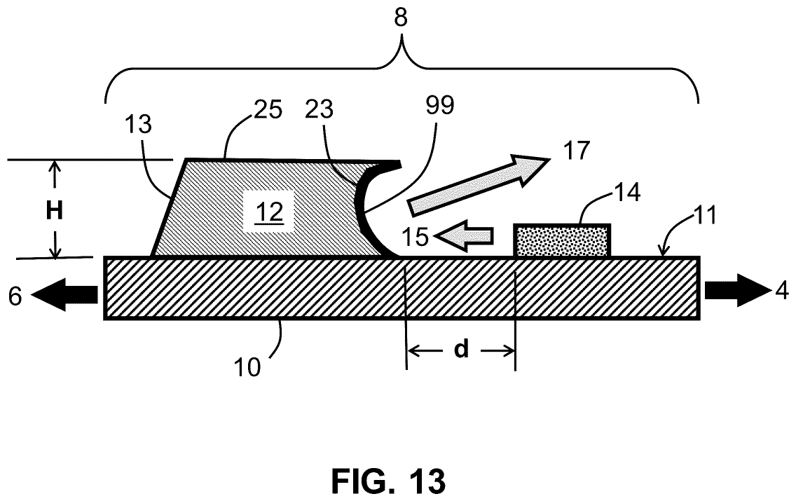

FIG. 13 shows a schematic cross-sectional, elevation view of an example of an open (unencapsulated) micro-LED display unit 8, according to the present disclosure. In this example, reflective surface 99 of front face 23 of micro-reflector 12 is curved in a concave manner so as to optimally direct and guide reflected light ray 17 in a more controlled and precise fashion in forward direction 4. Rear surface 13 is flat in this example.

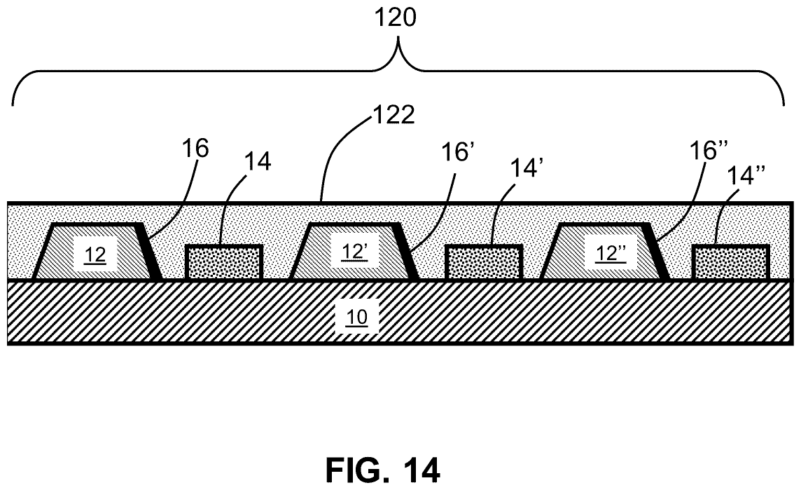

FIG. 14 shows a schematic cross-sectional, elevation view of an example of an encapsulated micro-LED display 120, according to the present disclosure. A first array of micro-reflectors 12, 12′, and 12″ (with reflective surfaces 16, 16′, and 16″, respectively) and a second, aligned array of micro-LEDs 14, 14′, and 14″ are disposed on substrate 10, which are conformally encapsulated in transparent layer 122. Transparent layer 122 may initially comprise a polymeric material (e.g., acrylics, silicones, urethanes, or parylene), or a two-part epoxy composition (A+B; or A then B; or B then A) that is poured, sprayed, spun on, 3-D printed, or otherwise chemically or physically deposited onto substrate 10, conformally covering the first and second arrays of micro-LEDS 14, 14′, and 14″ and micro-reflectors 12, 12′, and 12″, respectively. An initially-liquid material then solidifies as a substantially smooth, transparent coating 122. The thickness of transparent coating 122 may be the same as, or about the same as, the thickness of substrate 10. In this example (FIG. 14), three micro-LEDs 14, 14′, 14″ and three micro-reflectors 12 12′, 12″ are illustrated. However, in other embodiments, micro-LED display 120 may have more than three micro-LEDs 14, 14′, 14″, etc. and more than three micro-reflectors 12 12′, 12″, etc.

In some embodiments, the micro-reflecting structures be made of the same material as the substrate in an integrated fashion, or they may be made of a different material that is bonded or deposited onto substrate.

In some embodiments, the micro-reflecting structures may be fabricated by using a laser etching or chemical removal process. Alternatively, the micro-reflector structures may be formed on the substrate by using a positive deposition process, such as chemical or physical vapor deposition, 3-D printing, and/or electroplating.

In some embodiments, a laminated glass panel, window, or windshield may include one or more additional layers of anti-reflection, solar comfort, auto-tinting, and/or general appearance enhancing thin films and/or coatings.

In some embodiments, the reflective layer may have a thickness of between about 5 nanometers and about 3 microns.

In some embodiments, one or more surfaces of the micro-LED may be coated with a reflective layer such that light is only emitted from an uncoated side or sidewall of the micro-LED. In these embodiments, the uncoated sidewall of the micro-LED that emits light unidirectionally may directly face the reflective sidewall of the micro-reflector.

In some embodiments, the upper (topmost) surface of micro-reflector is not coated with a reflective coating.

In some embodiments, the reflective layer may be conformally deposited over the shaped and/or angled face(s) of the micro reflector by using, for example, Chemical Vapor Deposition (CVD, plasma-enhanced CVD (PECVD), ultrahigh vacuum CVD (UHVCVD), rapid thermal CVD (RTCVD), metalorganic CVD (MOCVD), low-pressure CVD (LPCVD), limited reaction processing CVD (LRPCVD), atomic layer deposition (ALD), physical vapor deposition (PVD), chemical solution deposition, molecular beam epitaxy (MBE), and/or other similar processes in combination with wet or dry etch processes, such as lithography combined with masking.

In some embodiments, the micro-LED may include a single LED element. In other embodiments, the micro-LED 14 may comprise a plurality of micro-LED elements, such as, for example, a red micro-LED element, a green micro-LED element, and/or a blue micro-LED element (not separately shown). The multi-color micro-LEDs may be formed from a range of suitable material(s), such as, for example, semiconductor materials (e.g., silicon, gallium nitride, indium gallium nitride, etc.) and sapphire, depending on the desired emission color of the respective micro-LED. For example, gallium nitride (GaN) may be used for blue micro-LEDs, indium gallium nitride (InGaN) may be used for green micro-LEDs, and aluminum gallium indium phosphide (AlGaInP) may be used for red micro-LEDs.

In some embodiments, a laminated, micro-LED display may be integrated into a window, windshield, or mirror of a vehicle, wherein the vehicle is selected from the group consisting of automobiles, trucks, bicycles, motorcycles, farm equipment, construction equipment, boats, trains, and airplanes.

In some embodiments, the reflective rear portion of at least one of the one or more internal surfaces of a recessed volume comprises less than or equal to about 50% of a total surface area of each recessed volume.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

What is claimed is:

1. A micro-Light Emitting Diode (micro-LED) display unit, comprising
a substrate;
a micro-LED disposed on the substrate; and
a micro-reflector disposed on the substrate adjacent to the micro-LED;
wherein the micro-reflector comprises a reflective surface facing the micro-LED;
wherein the micro-LED is a side-emitting micro-LED;
wherein the micro-reflector has a height (H) above an upper surface of the substrate that is less than or equal to about 50 microns; and
wherein a distance (d) between the micro-LED and the micro-reflector is less than or equal to about 0.5 mm.

2. The micro-LED display unit of claim 1,
wherein the reflective surface is a flat surface that is oriented at an angle (q) with respect to a line that is perpendicular to the substrate;
wherein the angle (□) ranges from about −30 degrees to about +30 degrees; and
wherein a positive value of the angle (□) is measured in a clockwise direction.

3. The micro-LED display unit of claim 1, wherein the micro-reflector has a trapezoidal cross-sectional shape.

4. The micro-LED display unit of claim 1, wherein light emitted from the micro-LED display unit is emitted in a collimated fashion at an angle (q) with respect to the substrate, where q is less than or equal to about 30 degrees.

5. The micro-LED display unit of claim 1, further comprising a layer of a transparent material covering and conformally encapsulating the micro-LED, the micro-reflector, and an upper surface of the substrate.

6. The micro-LED display unit of claim 1, wherein the substrate is transparent.

7. The micro-LED display unit of claim 1, wherein an upper surface of the substrate is reflective.

8. The micro-LED display unit of claim 1, wherein the micro-reflector and the substrate are made monolithically of a single material in an integrated fashion.

9. The micro-LED display unit of claim 1, wherein the substrate is curved.

10. A laminated, micro-Light Emitting Diode (micro-LED) display, comprising:
a substrate, comprising a frontside, a backside, and a plurality of micro-LEDs disposed on the frontside of the substrate;
a first sheet of a first transparent material, comprising a first frontside, a first backside, and a plurality of recessed volumes;
a reflective coating disposed on a rear portion of each respective one of the plurality of recessed volumes; and
a second sheet of a second transparent material that is bonded and laminated to the backside of the substrate; and
wherein each recessed volume comprises a respective one of the plurality of micro-LEDs.

11. The laminated, micro-LED display of claim 10, wherein each respective one of the recessed volumes has a triangular, semi-circular, or oval cross-sectional shape.

12. The laminated, micro-LED display of claim 10, wherein each respective one of the recessed volumes has a curved, triangular, cross-sectional shape with two curved sidewalls.

13. The laminated, micro-LED display of claim 10, wherein each respective one of the recessed volumes has a trapezoidal or inverted trapezoidal cross-sectional shape.

14. The laminated, micro-LED display of claim 10, wherein each respective one of the recessed volumes has an inverted cross-sectional parabolic shape.

15. The laminated, micro-LED display of claim 10, wherein each respective one of the recessed volumes has a concave reflecting surface and a convex opposing surface.

16. The laminated micro-LED display of claim 10, wherein the laminated micro-LED display is integrated into a window, windshield, and/or mirror of a vehicle, wherein the vehicle is selected from the group consisting of automobiles, trucks, bicycles, motorcycles, farm equipment, construction equipment, boats, trains, and airplanes.

17. The laminated, micro-LED display of claim 16, wherein the laminated, micro-LED display is integrated as a Heads-Up Display (HUD) in a front windshield of an automobile.

18. The laminated, micro-LED display of claim 16, the laminated, micro-LED display is configured as a Center High Mounted Stop Light (CHMSL) disposed in a rear windshield of an automobile.

19. A method of fabricating a laminated, micro-Light Emitting Diode (micro-LED) display, comprising:
(a) providing a first sheet of a first transparent material with a first frontside and a first backside;
(b) fabricating a plurality of recessed volumes into the first backside of the first sheet, wherein each respective one of the plurality of recessed volumes comprises one or more internal surfaces that define a cross-sectional shape of each respective one of the plurality of recessed volumes;
(c) depositing a reflective coating onto a reflective rear portion of at least one of the one or more internal surfaces of each respective one of the plurality of recessed volumes;
(d) providing a substrate with a second frontside, a second backside, and a plurality of micro-Light Emitting Diodes (micro-LEDs) disposed on the second frontside of the substrate;
(e) aligning the plurality of micro-LEDs to the plurality of recessed volumes, wherein each respective one of the plurality of recessed volumes comprises a respective one of the plurality of micro-LEDs;
(f) bonding the second frontside of the substrate to the first backside of the first sheet, thereby encapsulating each respective one of the plurality of micro-LEDs inside of each respective one of the plurality of the recessed volumes;
(g) providing a second sheet of a second transparent material; and
(h) adhesively bonding and laminating the second sheet to the second backside of the substrate.

20. The method of claim 19, wherein the reflective rear portion of at least one of the one or more internal surfaces comprises less than or equal to about 50% of a total surface area of each respective one of the plurality of recessed volumes.
